(19) United States
(12) Patent Application Publication
(10) Pub. No.: US 2002/0017243 A1
(43) Pub. Date: Feb. 14, 2002

(54) Showerhead in chemical-enhanced chemical vapor deposition equipment

(76) Inventor: Sung Gyu Pyo, Kyungki-Do (KR)

Correspondence Address: Finnegan, Henderson, Farabow,, Garrett & Dunner, L.L.P., 1300 I Street, N.W., Washington, DC, 20005-3315, US

(21) Appl. No.: 09/880,810

(22) Filed: Jun. 15, 2001

(30) Foreign Application Priority Data
Jun. 15, 2000 (KR) 2000-32919

(51) Int. Cl. C23C 16/00

(52) U.S. Cl. 118/715

(57) ABSTRACT

There is disclosed a showerhead in chemical-enhanced chemical vapor deposition (CECVD) equipment, which includes a shower zone for containing a deposition source and a shower zone for containing a chemical enhancer. The shower zone for containing the deposition source is located over the shower zone for containing the chemical enhancer, and the shower zone for containing the deposition source is consisted of double zones with being separated by a blocker buffer plate. Step coverage, the deposition speed, texture, adhesive characteristic, of a thin copper metal, realization of reappearance of the metal deposition process and prevention of depositing a deposition source within the showerhead to thus prohibit generation of particles are realized thereby.

### BACKGROUND OF THE INVENTION

1. Field of the Invention

The invention relates generally to a showerhead in chemical-enhanced chemical vapor deposition (CECVD) equipment. More particularly, the invention relates to a showerhead in CECVD equipment capable of uniformly dispersing a chemical enhancer and a deposition source, thus improving the characteristic of a thin metal film.

2. Description of the Prior Art

Generally, in the process of manufacturing a semiconductor device, a process of depositing a thin metal film is useful in implementing high-speed devices and high-integrated devices. The process employs various methods, such as physical vapor deposition (PVD) method, electroplating method, electroless-plating method, chemical vapor deposition (CVD) method.

Due to higher-integration in next-generation semiconductor devices, good step coverage and contact fill characteristics are required since the size of the contact is reduced and the step coverage is increased. A conventional PVD method, however, is limited when depositing a thin metal film in a semiconductor device having an ultra-fine structure. Therefore, there is a growing interest in depositing a thin metal film using organic metal chemical vapor deposition (MOCVD).

The conventional CVD apparatus includes a deposition source supply apparatus for storing a deposition source, and a showerhead for uniformly dispersing the deposition source supplied from the supply apparatus onto a reaction chamber on which wafers are mounted. The showerhead comprises a shower zone containing the deposition source supplied from the reaction chamber and a deposition source spray nozzle for spraying the contained deposition source into the reaction chamber.

These CVD apparatuses are employed to deposit metals such as copper, aluminum, tungsten, silver, platinum, tantalum, titanium, etc., thus forming a thin metal film. Since the deposition speed of a thin copper film by the CVD method is slow, there is a problem in commercialization. Also, when the CVD method is employed to deposit a thin copper film, it is disadvantageous in cost compared to the widely-used electroplating process since the CVD method has a poor adhesion characteristic, inferior texture, and slow deposition speed.

Thus, in case of depositing a thin Cu film using the CVD method, chemical adhesives, such as catalysts, are used along with a deposition source in order to improve the deposition speed, texture, adhesion characteristic, etc. of the thin Cu film. The conventional CVD apparatus, however, has difficulty in uniformly spraying chemical adhesives such as catalyst, which are capable of accelerating the deposition speed, since it does not have an additional apparatus for uniformly spraying the chemical adhesives.

More particularly, since the conventional CVD apparatus does not have an apparatus for uniformly spraying the chemical adhesive, it must deposit a thin Cu film by a CVD method after flowing the chemical adhesive into the showerhead. Because of this, Cu is deposited on the showerhead. Therefore, reappearance of Cu deposition process could not be realized and complete surface adhesion reaction upon deposition of Cu could not be induced. As a result, a thin Cu film, having a good film quality, can not be obtained.

### SUMMARY OF THE INVENTION

The present invention provides a showerhead used in the chemically enhanced chemical vapor deposition (CECVD) equipment in which a chemical process can be uniformly processed when a thin metal film is deposited by CVD method using chemical process such as catalyst, thus improving increasing the deposition speed, texture, adhesive characteristic of a thin copper metal.

In order to accomplish the above, a showerhead used in a CECVD equipment according to the present invention comprises a deposition source inlet for introducing a deposition source supplied from a deposition source supply apparatus into a first shower zone; a blocker buffer plate for uniformly introducing the deposition source introduced into the first shower zone into a second shower zone; a deposition source spray nozzle for the deposition source introduced into the second shower zone into a reaction chamber; a chemical enhancer inlet for introducing the chemical enhancer supplied from a chemical enhancer supply apparatus into a third shower zone; and a chemical spray nozzle for spraying the chemical enhancer introduced into the third shower zone into the reaction chamber.

### BRIEF DESCRIPTION OF THE DRAWINGS

The aforementioned aspects and other features of the present invention will be explained in the following description, taken in conjunction with the accompanying drawing, wherein:

FIG. 1 is a cross-sectional view of a showerhead used in chemical-enhanced chemical vapor deposition equipment.

### DETAILED DESCRIPTION OF PREFERRED EMBODIMENTS

The present invention will be described in detail by way of a preferred embodiment with reference to accompanying drawings.

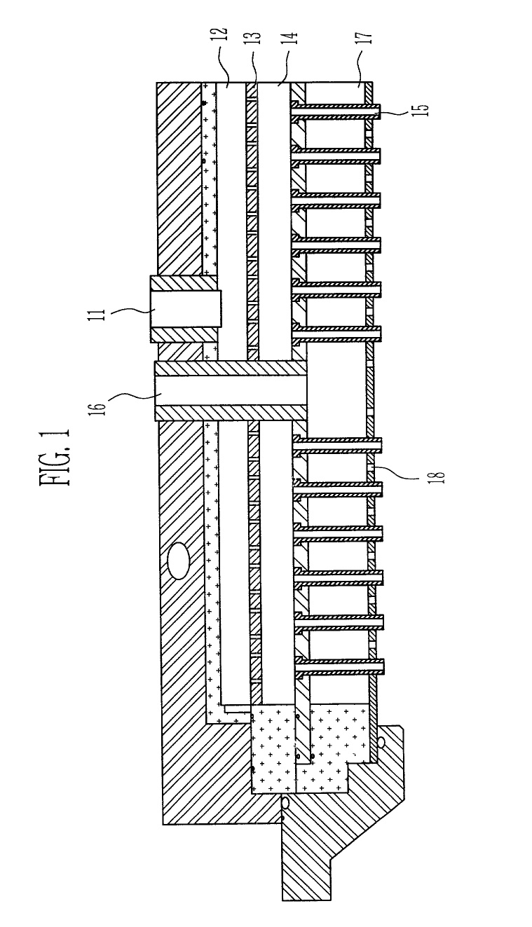

FIG. 1 is a cross-sectional view of a showerhead in chemical-enhanced chemical vapor deposition equipment.

A deposition source is introduced into a first showerhead zone 12 via a deposition source inlet 11. The deposition source introduced into the first shower zone 12 is then uniformly introduced into a second shower zone 14 by means of a blocker buffer plate 13. Next, the deposition source introduced into the second shower zone 14 is sprayed into the reaction chamber by means of a deposition source spray nozzle 15. Meanwhile, a chemical enhancer, such as catalyst, is introduced into a third shower zone 17 via a chemical enhancer inlet 16. The chemical enhancer introduced into the third shower zone 17 is then sprayed into the reaction chamber by a chemical enhancer spray nozzle 18.

At this time, the first and second shower zones 12 and 14, containing the deposition source, and the third shower zone 17, containing the chemical enhancer, are completely separated from each other. Also, the first and second shower zones 12 and 14 are located over the third shower zone 17. The first shower zone 12 and the second shower zone 14 are separated by the blocker buffer plate 13.

The blocker buffer plate 13 for separating the first and second shower zones 12 and 14 and for uniformly introducing the deposition source introduced into the first shower zone 12 into the second shower zone 14 may be made of a material such as aluminum. The blocker buffer plate 13 is formed as a net structure in which a plurality of holes each spaced by a given distance are formed. Also, the deposition source spray nozzle 15 is made of materials such as SUS, Ni, Al₂O₃, ceramics, etc. and is formed as a cylindrical structure having a diameter of 0.1 to 5 mm. Further, the arrangement of the deposition source spray nozzle 15 and the chemical enhancer spray nozzle 18 may be a regular square arrangement, a regular triangle arrangement, or a spiral arrangement.

The showerhead used in the CECVD equipment, according to the present invention, can deposit a single-metal thin film, such as copper (Cu), silver (Ag), Platinum (Pt), aluminum (Al), tungsten (W), tantalum (Ta), titanium (Ti), rubidium (Ru), on a wafer, by supplying the source, used for the formation of a thin metal film into the reaction chamber via the deposition source spray nozzle 15. Also, the showerhead can deposit a thin film of an oxide material, a nitride material, or an oxy-nitride material, such as a single metal. More particularly, the above-mentioned precursors are used as a deposition source. Before depositing a thin metal film using the showerhead used in the CECVD equipment, to improve the step coverage, texture, adhesion characteristic, of the thin metal film, a chemical enhancer is supplied into the third shower zone 17 via the chemical enhancer inlet 16. The supplied chemical enhancer is sprayed into the reaction chamber using the chemical enhancer spray nozzle 18. This chemical enhancer may be selected depending on what deposition source material is used. It may be a chemical enhancer in a liquid state, such as an iodine-containing liquid compound, H(hfac)½H₂O, H(hfac), TMVS, a chemical enhancer in a gaseous state, such as pure iodine gas, iodine-containing gas, water vapor, and a chemical enhancer in a liquid state or gaseous state such as F, Cl, Br, I, At elements, being group-7 elements in the periodic table and in liquid or gaseous state of their mixture. The chemical processing using the chemical enhancers may be performed for 1 second to 10 minutes and may be performed as a single process or multiple times of twice to ten times. At a given time after the chemical enhancers are first sprayed into the reaction chamber, the deposition source is sprayed to form a thin metal film.

Meanwhile, the chemical enhancer introduced into the chemical enhancer inlet 16 is introduced from a chemical enhancer supply apparatus, being another component of the CECVD apparatus. The chemical enhancer supply apparatus includes a canister into which chemical enhancer, such as a bubbler or a catalyst is filled, a pressurized gas inlet line for introducing pressurized gas into the canister, and a chemical enhancer outlet line for transferring the chemical enhancer to a vaporizer such as a liquid delivery system (LDS), by pressure from the inlet line.

The liquid delivery system (LDS) may include a direct liquid injection (DLI), control evaporation mixer (CEM) and a vaporizer from an orifice scheme or spray scheme. Also, the pressurized gas may include argon (Ar) or helium (He) with the pressure in a range of 10 to 200 psi.

As mentioned above, the present invention applies to a showerhead in CECVE equipment. The showerhead includes three zones in which a shower zone for containing a deposition source and a shower zone for containing a chemical enhancer are separated and a shower zone for containing the deposition source is separated by a blocker buffer plate. Thus, it not only improves step coverage, deposition speed, texture, adhesive characteristic, of a thin copper metal but also realizes reappearance of the metal deposition process, thus improving yield and reliability, reducing cost and increasing the throughput of devices. In addition, the present invention can prevent depositing a deposition source within the showerhead, which prohibits generation of particles.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed are:

1. A showerhead in a chemical-enhanced chemical vapor deposition (CECVD) apparatus comprising:
a deposition source inlet for introducing a deposition source supplied from a deposition source supply apparatus into a first shower zone;
a blocker buffer plate for uniformly introducing the deposition source introduced into the first shower zone into a second shower zone;
a deposition source spray nozzle for spraying the deposition source introduced into the second shower zone into a reaction chamber;
a chemical enhancer inlet for introducing a chemical enhancer supplied from a chemical enhancer supply apparatus into a third shower zone; and
a chemical spray nozzle for spraying the chemical enhancer introduced into the third shower zone into the reaction chamber.

2. The showerhead according to claim 1, wherein said first and second shower zones for containing the deposition source and said third shower zone for containing the chemical enhancer are completely separated from each other.

3. The showerhead according to claim 1, wherein said first and second shower zones are located over said third shower zone.

4. The showerbead according to claim 1, wherein said blocker buffer plate is made of aluminum and has a net structure in which a plurality of holes each having a fixed distance from each other is formed.

5. The showerhead according to claim 1, wherein said deposition source spray nozzle is made of one or more materials selected from SUS, Ni, Al₂O₃ and ceramics and is formed as a cylindrical structure having a diameter of 0.1 to 5 mm.

6. The showerhead according to claim 1, wherein said deposition source spray nozzle and chemical enhancer spray nozzle has one of a regular square arrangement, a regular triangle arrangement, and a spiral arrangement.

7. The showerhead according to claim 1, wherein said deposition source is one of a single-metal precursor selected from copper, silver, platinum, aluminum, tungsten, tantalum, titanium, rubidium, a single-metal oxide material precursor, a single-metal nitride material precursor, and a single-metal oxy-nitride material precursor.

8. The showerhead according to claim 1, wherein said chemical enhancer is a chemical enhancer having a liquid state selected from iodine-containing liquid compound, H(hfac)½H₂O, H(hfac), and TMVS.

9. The showerhead according to claim 1, wherein said chemical enhancer is a chemical enhancer having a gaseous state selected from pure iodine gas, iodine-containing gas, and water vapor.

10. The showerhead according to claim 1, wherein said chemical enhancer is one of a chemical enhancer having a liquid state and a gaseous state selected from F, Cl, Br, I, At elements and a chemical enhancer having liquid and gaseous states of their mixture.

11. The showerhead according to claim 1, wherein chemical processing using said chemical enhancer is performed for 1 second to 10 minutes.

12. The showerhead according to claim 1, wherein chemical processing using said chemical enhancer is performed as a single process or multiple times of twice to ten times.
